(19) United States
(12) Patent Application Publication
(10) Pub. No.: US 2009/0134934 A1
(43) Pub. Date: May 28, 2009

(54) ELECTRONIC DEVICE

(75) Inventors: Chun-Lung Hung, Tu-Cheng (TW); Wen-Ming Chen, Shenzhen City (CN); Wang-Chang Duan, Shenzhen City (CN); Tao Wang, Shenzhen City (CN); Kun Huang, Shenzhen City (CN); Shi-Ming Zhang, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/168,882

(22) Filed: Jul. 7, 2008

(30) Foreign Application Priority Data
Nov. 26, 2007 (CN) 200710202677.3

(51) Int. Cl. H03K 17/60; H03K 17/56

(52) U.S. Cl. 327/478; 327/419

(57) ABSTRACT

An electronic device includes a power interface for transmitting power, an integrated circuit capable of resetting, and a switch circuit. The switch circuit is connected to the power interface for transmitting the power to the integrated circuit after the integrated circuit is reset and stop transmitting the power to the integrated circuit if the integrated circuit is resetting.

### BACKGROUND

1. Field of the Invention

The present invention relates to electronic devices, and particularly to an electronic device with a switch circuit for protecting an integrated circuit of the electronic device when the integrated circuit is reset.

2. Description of Related Art

Integrated circuits (IC) are widely used in electronic devices for processing data or power management. Generally, a complex IC (e.g., a microcontroller unit) performs a reset function to clear any pending errors or events so as to return to a normal condition or initial state. When performing the reset function, the IC becomes unstable and is vulnerable to voltage spikes and current surges.

Therefore, an improved electronic device is needed to address the aforementioned deficiency and inadequacies.

### SUMMARY

An electronic device includes a power interface for transmitting power, an integrated circuit capable of resetting, and a switch circuit. The switch circuit is connected to the power interface for transmitting the power to the integrated circuit after the integrated circuit is reset and to stop transmitting the power to the integrated circuit if the integrated circuit is resetting.

Other advantages and novel features of the present invention will become more apparent from the following detailed description of an embodiment/embodiments when taken in conjunction with the accompanying drawings, in which:

### BRIEF DESCRIPTION OF THE DRAWINGS

FIG. 1 is a schematic block diagram of an electronic device, and the electronic device includes a switch circuit;

FIG. 2 is a schematic diagram of the switch circuit in FIG. 1 in accordance with a first embodiment; and

FIG. 3 is a schematic diagram of the switch circuit in FIG. 1 in accordance with a second embodiment.

### DETAILED DESCRIPTION

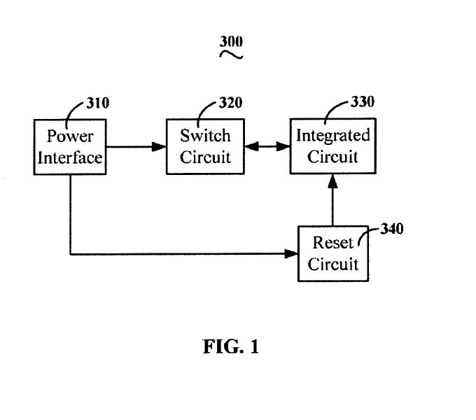

Referring to FIG. 1, an electronic device 300 includes a power interface 310, a switch circuit 320, an integrated circuit 330, and a reset circuit 340. The power interface 310 is configured for receiving power from an external or internal power source (not shown) to other components. The reset circuit 340 is coupled to the power interface 310 for receiving the power, generating a reset signal, and transmitting the reset signal to the integrated circuit 330. The integrated circuit 330 is able to perform a reset procedure upon receiving the reset signal. The switch circuit 320 is connected to the power interface 310 for transmitting the power to the integrated circuit 330 if the integrated circuit 330 completed the reset procedure.

There are two types of reset: internal reset (e.g., power on reset) and external reset (reset after receiving the reset signal from the reset circuit 340). While performing the reset procedure, the integrated circuit 330 sends a reset-in-process signal to the switch circuit 320. When the reset-in-process signal is transmitted to the switch circuit 320, the switch circuit 320 disconnects the power interface 310 to the integrated circuit 330. During the reset procedure, the integrated circuit 330 receives power from other power interface with a standard voltage. When the reset procedure is completed, the integrated circuit 330 sends a reset-completed signal to the switch circuit 320. After receiving the reset-completed signal, the switch circuit 320 conducts and connects the power interface 310 to the integrated circuit 330. The integrated circuit 330 performs power management function according to the detected power transmitted from the external or internal power source via the switch circuit 320.

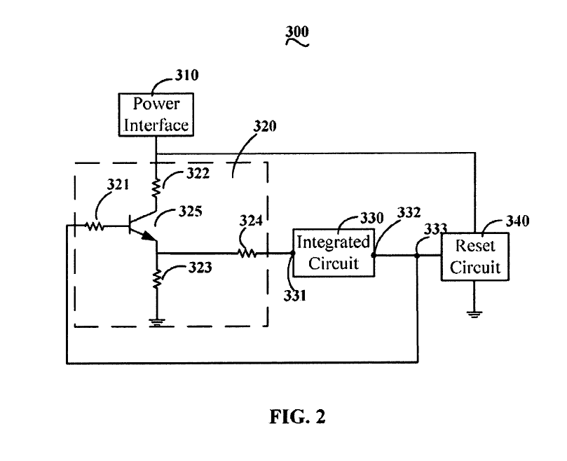

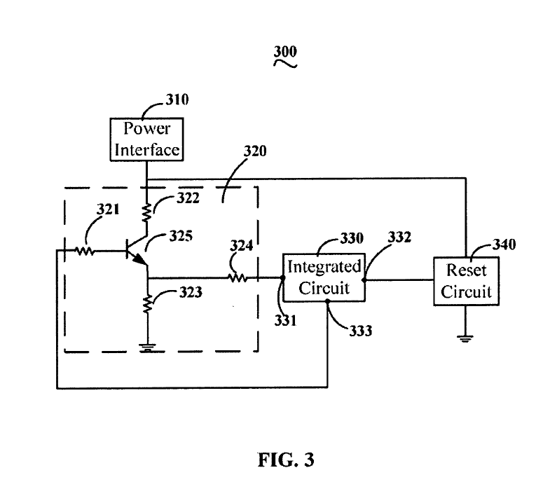

Referring to FIGS. 2 and 3, the integrated circuit 330 includes a detect pin 331, a reset pin 332, and a state node 333. The reset pin 332 is coupled to the state node 333 in FIG. 2, in this case, the integrated circuit 330 starts the reset procedure upon receiving the reset signal with a low voltage level. After the integrated circuit 330 performs the reset procedure, the integrated circuit 330 outputs a high voltage via the state node 333. The reset pin 332 is not connected to the state node 333 in FIG. 3 and the state node 333 is used for indicating whether the integrated circuit 330 has finished resetting.

The switch circuit 320 includes a first resistor 321, a second resistor 322, a third resistor 323, a fourth resistor 324, and a NPN Bipolar Junction Transistor (BJT) 325. The first resistor 321 is connected between the base of the BJT 325 and the state node 333. The second resistor 322 is connected between the collector of the BJT 325 and the power interface 310. The third resistor 323 is connected between the emitter of the BJT 325 and the ground. The fourth resistor 324 is connected between the emitter of the BJT 325 and the detect pin 331. The resistors 321, 322, 323, 324 are used for providing a suitable voltage to the integrated circuit 330. In other alternative embodiments, some of the resistors can be omitted, or have more resistors. The BJT 325 is used for connecting the power interface 310 to the integrated circuit 330 after receiving the reset-completed signal (i.e., high voltage level) from the state node 333.

For example, a voltage supplied by the power interface 310 may be 9.5 volts. The integrated circuit 330 will initiate the reset after receiving the reset signal from the reset circuit 340. The reset signal is a low voltage from reset circuit 340, this low voltage is outputted to the pin connected to the state node 333. This results in the state node 33 being pulled low and the BJT 325 being off. After the integrated circuit 330 performs the reset procedure, the integrated circuit 330 outputs a high voltage to the base of the BJT 325 via the state node 333, thus the BJT 325 is on and the power is transmitted to the detect pin 331 via the BJT 325. Therefore, the integrated circuit 330 is able to receive and detect the power received by the detect pin 331 to perform power management function. After the reset procedure of integrated circuit 330 is completed, the integrated circuit 330 is able to withstand electric power having voltage spikes and current surges because built-in internal protection circuitry will operate and protect the IC during normal operation.

In other alternative embodiments, the BJT 325 can be replaced by other transistors that conduct under low voltage level, such as field effect transistors. That is, the state node 333 of the integrated circuit 330 is low voltage level after the integrated circuit 330 is reset. In addition, the reset circuit 340 is optional, since the integrated circuit 330 is able to start reset according to software command or start reset automatically when powered on.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electronic device comprising:
a power interface for transmitting power;
an integrated circuit for generating a reset-in-process signal while the integrated circuit is performing the reset procedure and a reset-completed signal when the reset procedure is completed; and
a switch circuit for disconnecting the power interface and the integrated circuit after receiving the reset-in-process signal and connecting the power interface to the integrated circuit after receiving the reset-completed signal.

2. The electronic device as claimed in claim 1, wherein the integrated circuit comprises a detect pin connected to the switch circuit for receiving the power.

3. The electronic device as claimed in claim 2, wherein the integrated circuit comprises a state node for generating the reset-in-process signal and the reset-completed signal.

4. The electronic device as claimed in claim 3, wherein the switch circuit comprises a transistor for disconnecting the power interface and the detect pin after receiving the reset-in-process signal and connecting the power interface and the detect pin after receiving the reset-completed signal.

5. The electronic device as claimed in claim 4, wherein the transistor is a bipolar junction transistor, the base of the bipolar junction transistor is connected to the state node, the collector of the bipolar junction transistor is connected to the power interface, and the emitter of the bipolar junction transistor is connected to the ground.

6. The electronic device as claimed in claim 5, wherein the switch circuit further comprises a first resistor connected between the base and the state node.

7. The electronic device as claimed in claim 5, wherein the switch circuit further comprises a second resistor connected between the collector and the power interface.

8. The electronic device as claimed in claim 5, wherein the switch circuit further comprises a third resistor connected between the emitter and the ground.

9. The electronic device as claimed in claim 5, wherein the switch circuit further comprises a fourth resistor connected between the emitter and the detect pin.

10. The electronic device as claimed in claim 3, further comprising a reset circuit for generating a reset signal and transmitting the reset signal to the integrated circuit to reset the integrated circuit.

11. The electronic device as claimed in claim 10, wherein the integrated circuit comprises a reset pin for receiving the reset signal.

12. The electronic device as claimed in claim 11, wherein the reset pin is connected to the state node.

13. An electronic device comprising:
a power interface for transmitting power;
an integrated circuit capable of resetting; and
a switch circuit connected to the power interface for transmitting the power from the power interface to the integrated circuit after the integrated circuit is reset and to stop transmitting the power from the power interface to the integrated circuit if the integrated circuit is resetting.

14. The electronic device as claimed in claim 13, wherein the integrated circuit comprises a detect pin connected to the switch circuit for receiving the power.

15. The electronic device as claimed in claim 14, wherein the integrated circuit comprises a state node for representing whether the integrated circuit is reset.

16. The electronic device as claimed in claim 15, wherein the switch circuit comprises a transistor for transmitting the power to the detect pin after the integrated circuit is reset and stop transmitting the power to the detect pin if the integrated circuit is resetting.

17. The electronic device as claimed in claim 16, wherein the transistor is a bipolar junction transistor, the base of the bipolar junction transistor is connected to the state node, the collector of the bipolar junction transistor is connected to the power interface, and the emitter of the bipolar junction transistor is connected to the ground.

18. The electronic device as claimed in claim 15, further comprising a reset circuit for generating a reset signal and transmitting the reset signal to the integrated circuit to reset the integrated circuit.

19. The electronic device as claimed in claim 18, wherein the integrated circuit comprises a reset pin for receiving the reset signal.

20. The electronic device as claimed in claim 19, wherein the reset pin is connected to the state node.
